(19) United States
(12) Patent Application Publication
(10) Pub. No.: US 2025/0273472 A1
(43) Pub. Date: Aug. 28, 2025

(54) SEMICONDUCTOR STRUCTURE AND MANUFACTURING METHOD THEREOF

(71) Applicant: Powerchip Semiconductor Manufacturing Corporation, Hsinchu (TW)

(72) Inventors: Pei-Rong Ni, Hsinchu (TW); Chun-Lin Lu, Hsinchu City (TW); Hsiao-Chiang Lin, New Taipei City (TW); Shou-Zen Chang, Hsinchu City (TW)

(73) Assignee: Powerchip Semiconductor Manufacturing Corporation, Hsinchu (TW)

(21) Appl. No.: 18/928,206

(22) Filed: Oct. 28, 2024

(30) Foreign Application Priority Data
Feb. 27, 2024 (TW) 113107099

(51) Int. Cl. H01L 21/308; H01L 21/48; H01L 23/498; H01L 27/08

(52) U.S. Cl. CPC H01L 21/308; H01L 21/486; H01L 23/49827; H10D 1/68; H10D 84/212

(57) ABSTRACT

Disclosed is a semiconductor structure and a manufacturing method thereof. The manufacturing method of the semiconductor structure includes the following steps. A plurality of passive elements are formed in a substrate. The plurality of passive elements are arranged in an array in the substrate. A plurality of contact members are formed on the plurality of passive elements. The plurality of contact members correspond to the plurality of passive elements. A redistribution layer is formed on the substrate. The redistribution layer is electrically connected to a part of the plurality of passive elements through a part of the plurality of contact members.

### CROSS-REFERENCE TO RELATED APPLICATION

This application claims the priority benefit of Taiwan application serial no. 113107099, filed on Feb. 27, 2024. The entirety of the above-mentioned patent application is hereby incorporated by reference herein and made a part of this specification.

### BACKGROUND

### Technical Field

The disclosure relates to a structure and a manufacturing method thereof, and in particular to a semiconductor structure and a manufacturing method thereof.

### Description of Related Art

With the evolution of technology and market requirements, more and more elements (e.g., memories, logic chips, etc.) need to be packaged together to meet the requirements for high-performance computing. When manufacturing a large die, a single exposure area of a general photomask may not be sufficient to manufacture the large die, and a plurality of photolithography processes by splicing are required to manufacture the large die. In terms of an interposer, as the size increases, the quantity of photomasks required for each layer including a redistribution layer, a via, a passive element, etc. also increases. Further, the photomask for each layer is different for different products, which leads to an increase in manufacturing costs.

### SUMMARY

The disclosure provides a semiconductor structure and a manufacturing method thereof to lower manufacturing costs.

The manufacturing method of the semiconductor structure of the disclosure includes the following steps. A plurality of passive elements are formed in a substrate. The plurality of passive elements are arranged in an array in the substrate. A plurality of contact members are formed on the plurality of passive elements. The plurality of contact members correspond to the plurality of passive elements. A redistribution layer is formed on the substrate. The redistribution layer is electrically connected to a part of the plurality of passive elements through a part of the plurality of contact members.

In an embodiment of the disclosure, in a process of forming the plurality of passive elements in the substrate, each different region of the substrate is exposed through a passive element photomask.

In an embodiment of the disclosure, forming the plurality of contact members on the plurality of passive elements includes respectively exposing different regions of the substrate through a passive element photomask.

In an embodiment of the disclosure, forming the redistribution layer on the substrate includes enabling a first photomask to correspond to a first subregion, and forming a first feature of the redistribution layer in the first subregion of the substrate through the first photomask; and enabling a second photomask to correspond to a second subregion, and forming a second feature of the redistribution layer in the second subregion of the substrate through the second photomask. A pattern of the first photomask is different from a pattern of the second photomask.

In an embodiment of the disclosure, the first feature and the second feature are horizontally connected.

In an embodiment of the disclosure, the substrate includes a plurality of die regions. An area of each of the plurality of die regions is greater than a single maximum exposure area of the first photomask.

In an embodiment of the disclosure, a size of the passive element photomask is smaller than a size of the first photomask.

In an embodiment of the disclosure, the part of the plurality of passive elements includes a dummy passive element.

In an embodiment of the disclosure, the manufacturing method further includes forming a through substrate via in the substrate.

The semiconductor structure of the disclosure includes a plurality of passive elements, a plurality of contact members, and a redistribution layer. The plurality of passive elements are arranged in an array in a substrate. The plurality of contact members are correspondingly disposed on the plurality of passive elements and in direct contact with the plurality of passive elements. The plurality of contact members include a first contact member and a second contact member. The redistribution layer is disposed on the substrate. The redistribution layer is electrically connected to the corresponding passive element through the first contact member, and the second contact member is not electrically connected to the redistribution layer.

In an embodiment of the disclosure, the semiconductor structure further includes a dielectric layer disposed on the substrate and laterally surrounding the plurality of contact members and the redistribution layer. A top surface of the second contact member is encapsulated by the dielectric layer.

In an embodiment of the disclosure, the semiconductor structure further includes a through substrate via disposed in the substrate. A top surface of the plurality of contact members is flush with a top surface of the through substrate via.

Based on the above, in the disclosure, the plurality of passive elements arranged in the array are formed in the substrate using the same photomask, and the required passive element is selected for an electrical connection using a distribution design of the redistribution layer. As a result, the burden of the layout design of the plurality of passive elements in the substrate can be reduced, and the flexibility of customization can be improved. In terms of manufacturing, the requirement for manufacturing the photomask of the plurality of passive elements can also be reduced, thereby reducing the manufacturing costs.

### BRIEF DESCRIPTION OF THE DRAWINGS

FIGS. 1A, 1B, 1C, 2A, 2B, 3A, 3B, 4A, 4B, 5A, 5B, 6, 7A, 7B, 8A, 8B, 9A, 9B, and 10 to 12 are schematic diagrams of a manufacturing process of a semiconductor structure according to an embodiment of the disclosure.

FIG. 13 is a cross-sectional schematic diagram of a semiconductor structure according to an embodiment of the disclosure.

### DESCRIPTION OF THE EMBODIMENTS

Reference will now be made to the drawings of the exemplary embodiments of the disclosure to provide a more comprehensive elaboration of the disclosure. However, the disclosure may also be embodied in various forms and is not limited to the embodiments described herein. Thicknesses of the layers and regions in the drawings are exaggerated for clarity. The same or similar reference numerals represent the same or similar elements, which will not be repeated one by one in the following paragraphs.

It should be understood that, although the terms “first”, “second”, “third”, etc. may be used herein to describe various elements, components, regions, layers, and/or parts, these elements, components, regions, layers, and/or parts should not be limited by these terms. These terms are only used to distinguish one element, component, region, layer, or part from another element, component, region, layer, or part. Thus, the “first element”, “component”, “region”, “layer”, or “part” discussed below may be referred to as a second element, component, region, layer, or part without departing from the teachings herein.

In addition, the directional terms mentioned herein, e.g. “on” or “below”, are only used to refer to the directions in the drawings and are not intended to limit the disclosure.

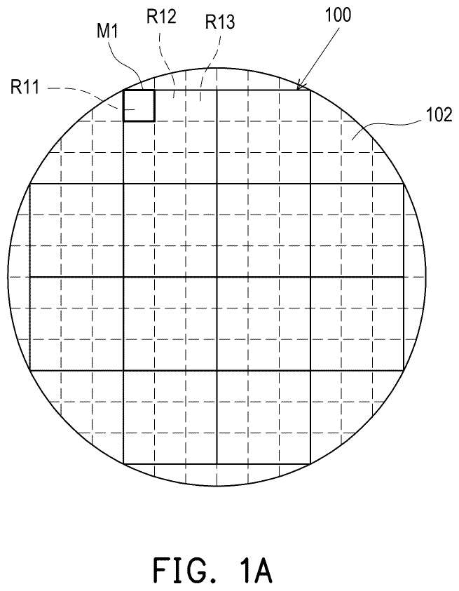

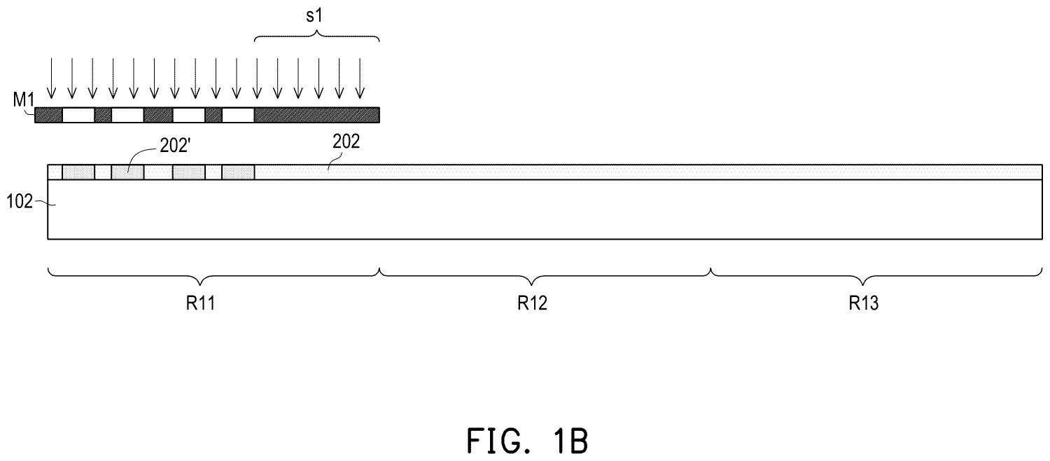

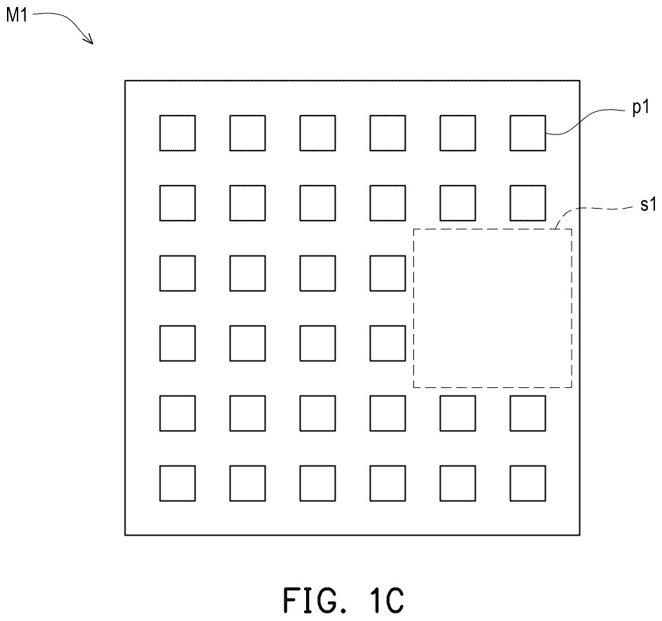

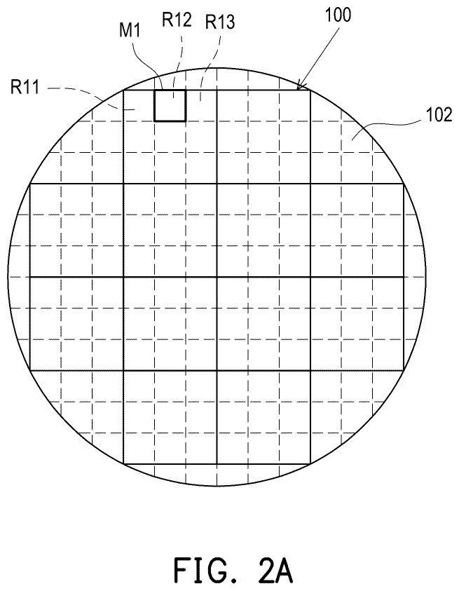

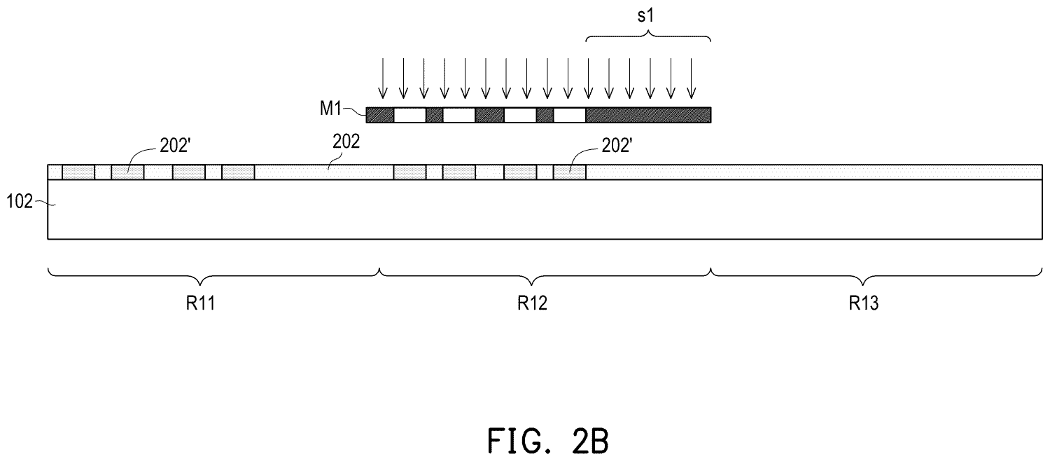

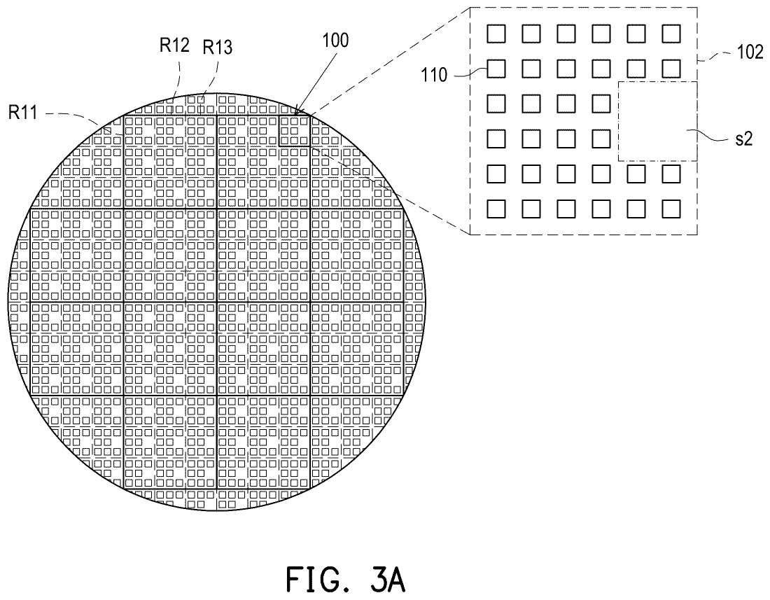

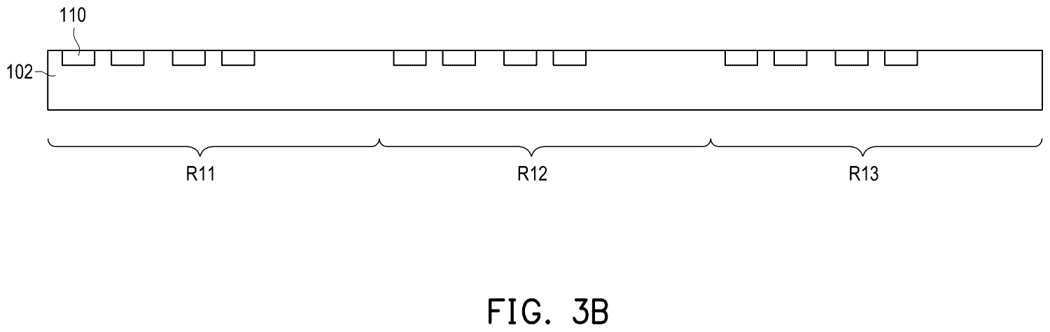

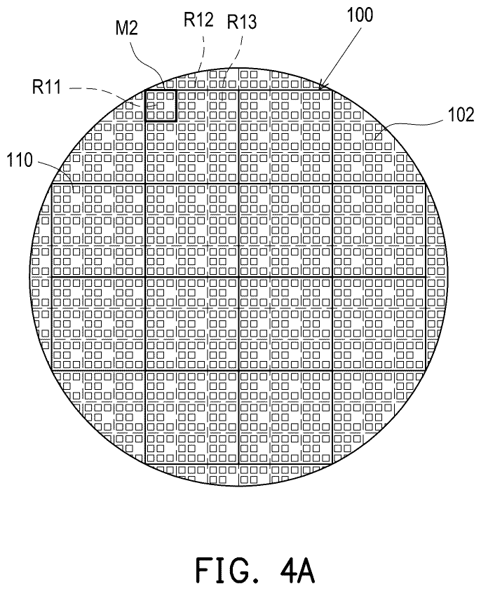

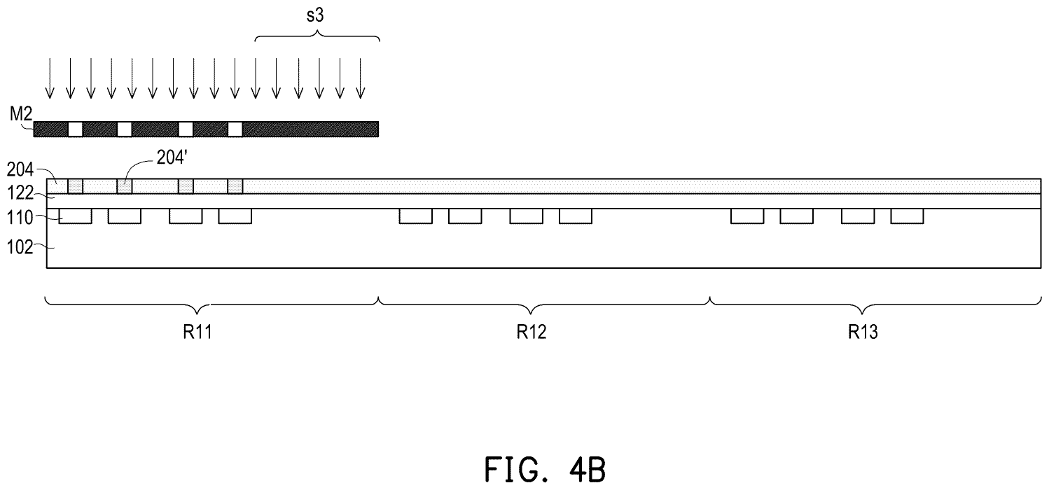

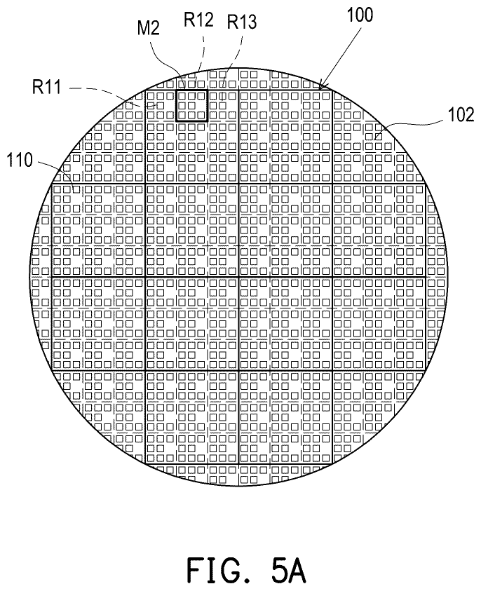

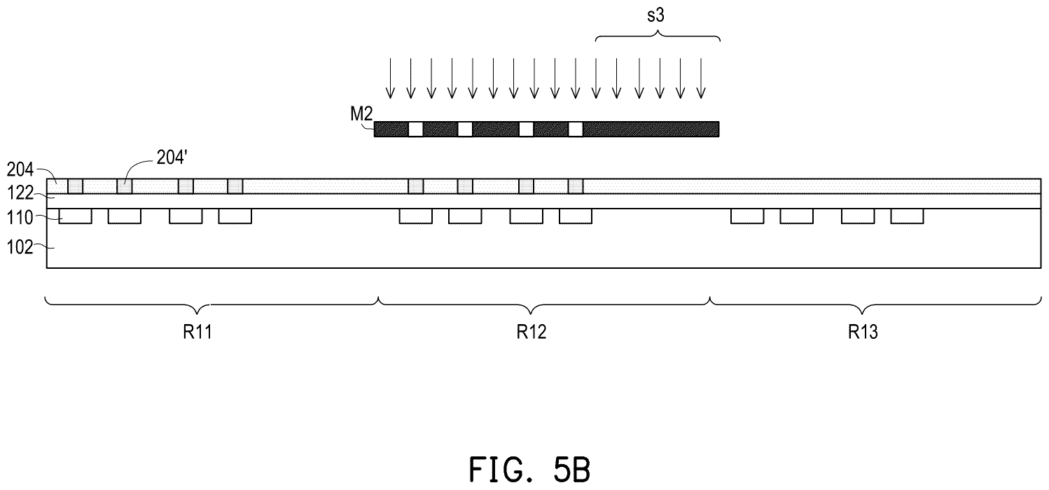

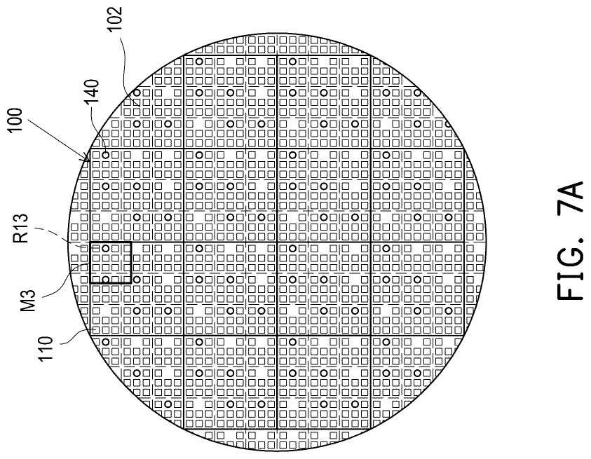

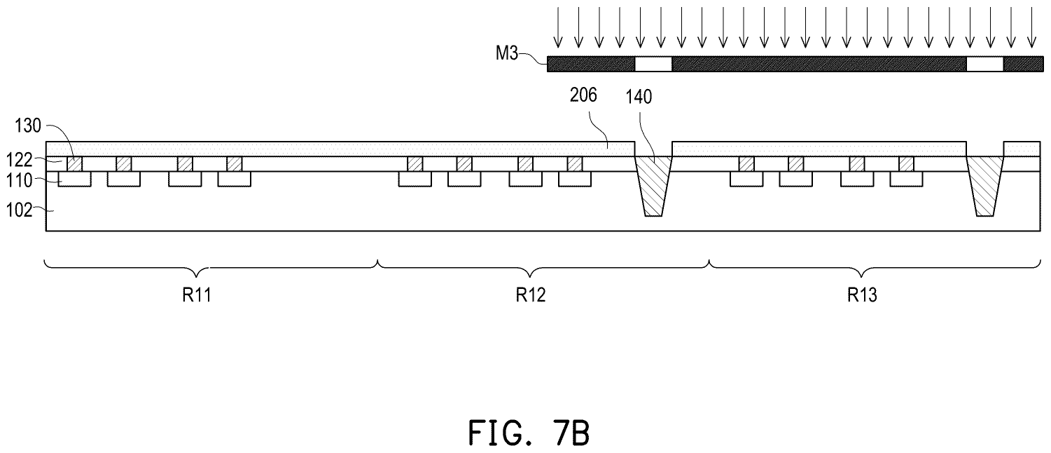

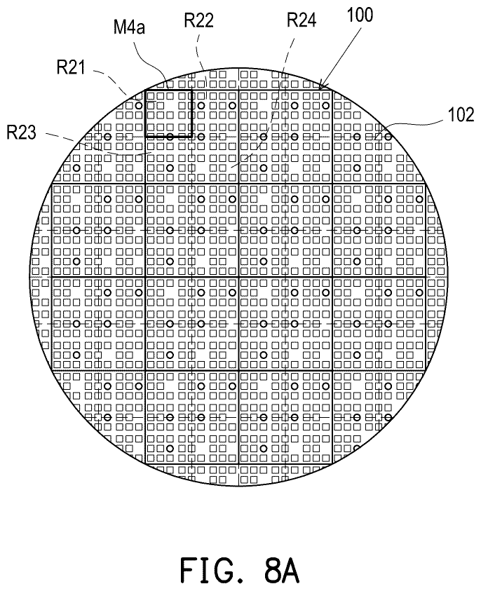

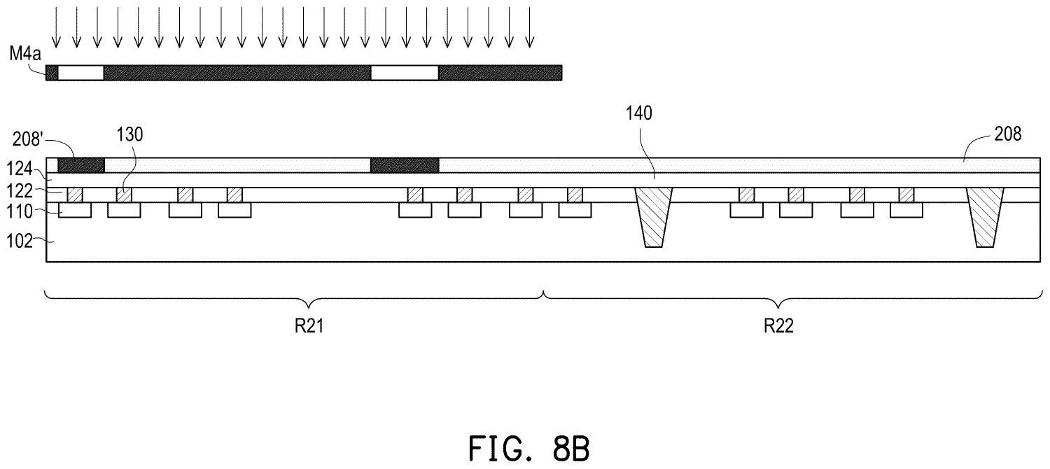

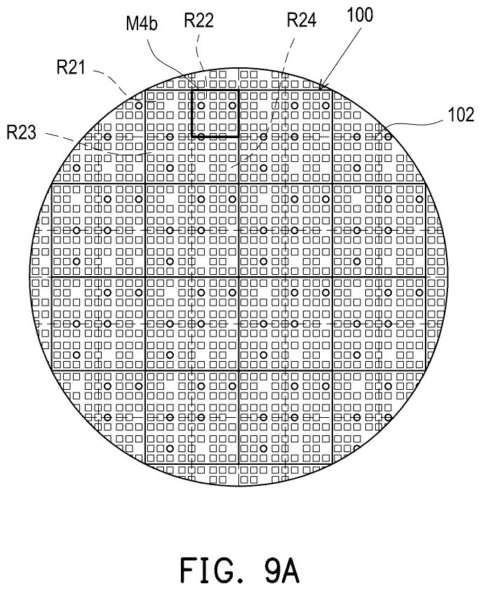

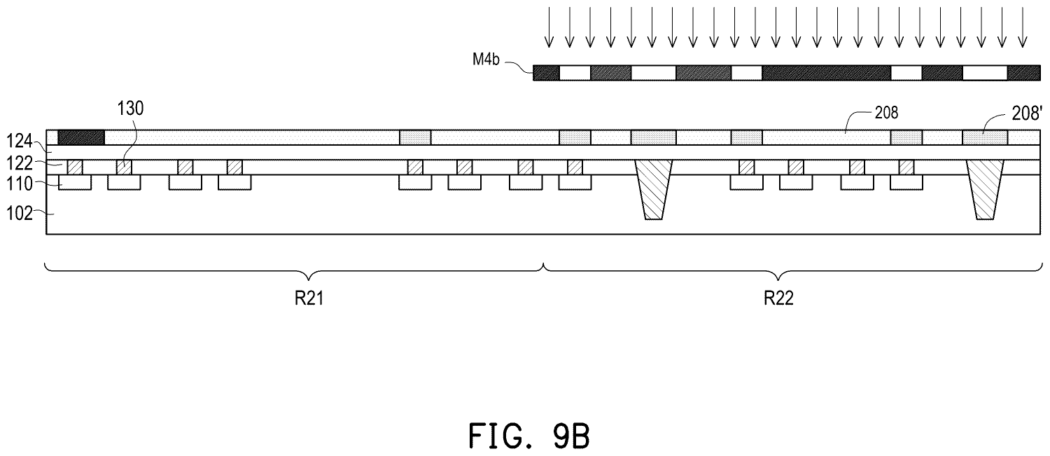

FIGS. 1A, 1B, 1C, 2A, 2B, 3A, 3B, 4A, 4B, 5A, 5B, 6, 7A, 7B, 8A, 8B, 9A, 9B, and 10 to 12 are schematic diagrams of a manufacturing process of a semiconductor structure according to an embodiment of the disclosure. FIGS. 1A, 2A, 3A, 4A, 5A, 7A, 8A, 9A, and 10A are top-view schematic diagrams. FIGS. 1B, 2B, 3B, 4B, 5B, 6, 7B, 8B, 9B, 11, and 12 are partial cross-sectional schematic diagrams. FIG. 1B is a partial cross-sectional schematic diagram of FIG. 1A. FIG. 1C is a top-view schematic diagram of a passive element photomask M1. FIG. 2B is a partial cross-sectional schematic diagram of FIG. 2A. FIG. 3B is a partial cross-sectional schematic diagram of FIG. 3A. FIG. 4B is a partial cross-sectional schematic diagram of FIG. 4A. FIG. 5B is a partial cross-sectional schematic diagram of FIG. 5A. FIG. 7B is a partial cross-sectional schematic diagram of FIG. 7A. FIG. 8B is a partial cross-sectional schematic diagram of FIG. 8A. FIG. 9B is a partial cross-sectional schematic diagram of FIG. 9A. For clarity, some members (e.g., a photoresist layer, a contact member, a dielectric layer, a redistribution layer, etc.) are omitted from FIGS. 1A, 2A, 3A, 4A, 5A, 7A, 8A, 9A, and 10. The omitted parts may be understood by referring to the corresponding cross-sectional diagrams.

Referring to FIGS. 1A, 1B, 1C, 2A, 2B, 3A, and 3B, a plurality of passive elements 110 are formed in a substrate 102. The plurality of passive elements 110 are arranged in an array in the substrate 102. Specifically, the substrate 102 is provided first. The substrate 102 includes a semiconductor substrate (made of, for example, silicon, silicon germanium, or other suitable semiconductor materials), a silicon-on-insulator (SOI) substrate, or a combination thereof. In some embodiments, a hard mask layer (not shown) may be formed on the substrate 102, and the disclosure is not limited thereto. In some embodiments, the substrate 102 may be divided into a plurality of die regions 100, so that the substrate 102 may be cut into a plurality of dies according to the plurality of die regions 100 in a subsequent process. In some embodiments, an area of a single die region 100 is greater than a single maximum exposure area of a general photomask, such as greater than 26 mm*33 mm. In some embodiments, the area of the single die region 100 is about four times the single maximum exposure area of the general photomask. The single maximum exposure area herein refers to a maximum range of the photomask that may be exposed in a single exposure and is independent of a pattern on the photomask.

Then, different regions of the substrate 102 are respectively exposed through the passive element photomask M1 using a splicing photolithography process to define positions where the passive elements are subsequently formed. For a pattern layout of the plurality of passive elements 110, a passive element pattern is basically not arranged in a position that overlaps a predetermined through substrate via. Other than that, the passive element patterns are arranged in an array in all other regions.

For example, as shown in FIGS. 1A and 1B, a first photoresist layer 202 is formed on the substrate 102. With the passive element photomask M1 as a mask, the passive element photomask M1 is enabled to correspond to a first subregion R11 first to expose the first photoresist layer 202 located in the first subregion R11, and an exposure region 202′ is formed in the first photoresist layer 202 in the first subregion R11. Then, as shown in FIGS. 2A and 2B, the passive element photomask M1 is enabled to correspond to a second subregion R12 to expose the first photoresist layer 202 located in the second subregion R12, and the exposure region 202′ is formed in the first photoresist layer 202 in the second subregion R12. The above steps are repeatedly performed, so that each subregion of the die region 100 is exposed through the passive element photomask M1, such that a pattern of the passive element photomask M1 is transferred to a different position in the die region 100. That is, each subregion of the die region 100 has the same pattern after being exposed through the passive element photomask M1.

It is noted that in FIG. 1A, to facilitate description, the single die region 100 is divided into nine subregions (including the first subregion R11, the second subregion R12, a third subregion R13, and a plurality of other unlabeled subregions) with dashed lines. A range of each subregion corresponds to a single maximum exposure range of the passive element photomask M1. That is, in FIG. 1A, the single maximum exposure area of the passive element photomask M1 is one-ninth of the die region 100. In other words, the area of the single die region 100 is about nine times the single maximum exposure area of the passive element photomask M1. However, the single maximum exposure area of the passive element photomask M1 (i.e., a size of the passive element photomask M1) may be adjusted according to the actual requirements, and the disclosure is not limited thereto. As the single maximum exposure range of the passive element photomask M1 changes, a quantity of subregions of the single die region 100 varies depending on the single maximum exposure range of the passive element photomask M1. In some embodiments, the entire substrate 102, that is, including the die region 100 and a region outside the die region 100, is exposed through the passive element photomask M1, so that subsequently formed passive elements may substantially cover the entire substrate 102.

In some embodiments, as shown in FIG. 1C, patterns p1 of the passive element photomask M1 may be arranged in an array in the passive element photomask M1. A partial space of the passive element photomask M1 may be left without a pattern (e.g., a blank pattern s1) to reserve a partial space of the substrate 102 for subsequent use by a through substrate via. In FIG. 1C, the pattern p1 and the blank pattern s1 of the passive element photomask M1 are only schematically shown and not intended to limit the disclosure. A layout and coverage of the pattern p1 and the blank pattern s1 of the passive element photomask M1 may be adjusted according to the actual requirements.

Since the area of the single die region 100 is larger than the maximum exposure area achievable in a single exposure by a general photomask that is and each of the plurality of passive elements 110 has the same pattern, the pattern layout of the plurality of passive elements 110 may be obtained through splicing by the same photomask rather than by different photomasks, so that different subregions of the die region 100 are exposed through the same photomask to transfer the pattern layout of the plurality of passive elements 110 to the die region 100. As a result, a quantity of photomasks required for the passive element 110 can be reduced, thereby reducing manufacturing costs and the number of quality tests of a photomask.

In some embodiments, the size of the passive element photomask M1 may be smaller or equal to the size of a general photomask. For example, the size of the passive element photomask M1 may be 0.1 to 1 times the size of the general photomask.

Referring to FIGS. 3A and 3B, after different regions of the substrate 102 are respectively exposed through the passive element photomask M1, the first photoresist layer 202 is developed (e.g., by removing the exposure region 202′ of the first photoresist layer 202) to obtain a patterned first photoresist layer (not shown). The passive element 110 may be formed in the substrate 102 thereafter by any known method. For example, taking the passive element 110 as a capacitor as an example, the patterned first photoresist layer may be used as a mask to perform etching on the substrate 102 to form a trench (not shown). After the patterned first photoresist layer is removed, a conducting layer, an insulating layer, and a conducting layer (not shown) may be sequentially formed in the trench to form the capacitor embedded in the substrate 102. However, the disclosure is not limited thereto. Other forming methods of a capacitor are also applicable to this embodiment. In addition, the passive element 110 may be other passive elements such as a resistor and an inductor, and the disclosure is not limited thereto.

Due to space concerns, eight passive elements 110 are schematically shown in each subregion of the die region 100 in FIG. 3A. However, it is noted that each subregion of the die region 100 has a passive element 110 corresponding to a position of a pattern of the passive element photomask M1, as shown in the partially enlarged view in FIG. 3A. It is evident that a quantity of the passive element 110 in a single subregion may be adjusted according to the actual requirements by adjusting a pattern layout of the passive element photomask M1. In addition, since the passive element photomask M1 has the blank pattern s1, each subregion of the die region 100 also has a region s2 corresponding to the blank pattern s1. The region s2 may be used as a space for subsequent configuration of a through substrate via. In addition, similar to FIG. 3A, FIGS. 4A, 5A, 7A, 8A, 9A, and 10 in subsequent descriptions also simplify the quantity of elements shown in each subregion in response to space restriction.

Referring to FIGS. 4A, 4B, 5A, 5B, and 6, a plurality of contact members 130 are formed on the plurality of passive elements 110. The plurality of contact members 130 correspond to the plurality of passive elements 110. For example, different regions of the substrate 102 are respectively exposed through a contact member photomask M2 using the splicing photolithography process to define positions where the contact members 130 are subsequently formed. For a pattern layout of the plurality of contact members 130, a contact member pattern is basically not arranged in a position that overlaps a predetermined through substrate via. The corresponding contact member patterns are arranged in all other regions corresponding to the passive elements 110.

Specifically, as shown in FIGS. 4A and 4B, a first dielectric layer 122 is formed on the substrate 102. Then, a second photoresist layer 204 is formed on the first dielectric layer 122. Thereafter, with the contact member photomask M2 as a mask, the contact member photomask M2 is enabled to correspond to the first subregion R11 first to expose the second photoresist layer 204 located in the first subregion R11, and an exposure region 204′ is formed in the first photoresist layer 202 in the first subregion R11. Then, as shown in FIGS. 5A and 5B, the contact member photomask M2 is enabled to correspond to a second subregion R12 to expose the second photoresist layer 204 located in the second subregion R12, and the exposure region 204′ is formed in the second photoresist layer 204 in the second subregion R12. The above steps are repeatedly performed, so that each subregion of the die region 100 is exposed through the contact member photomask M2, such that a pattern of the contact member photomask M2 is transferred to different positions in the die region 100. In some embodiments, a single maximum exposure area of the contact member photomask M2 is basically the same as the single maximum exposure area of the passive element photomask M1. Thus, a size of the contact member photomask M2 is basically the same as the passive element photomask M1.

In some embodiments, the pattern of the contact member photomask M2 may correspond to the pattern of the passive element photomask M1 to connect a subsequently formed contact member and the passive element 110. A partial space of the contact member photomask M2 may be left without a pattern (e.g., a blank pattern s3). The blank pattern s3 basically corresponds to the blank pattern s1 of the passive element photomask M1 or the region s2 of the die region 100 to reserve a partial space of the substrate 102 for subsequent use by a through substrate via.

A pattern layout of the plurality of contact members 130 may be obtained by splicing different subregions of the die region 100 through the same photomask, so that different subregions of the die region 100 are exposed through the same photomask, thereby transferring the pattern layout of the plurality of contact members 130 to the die region 100. As a result, a quantity of photomasks required for the contact member 130 may be reduced, thereby reducing the manufacturing costs and the number of quality tests of a photomask.

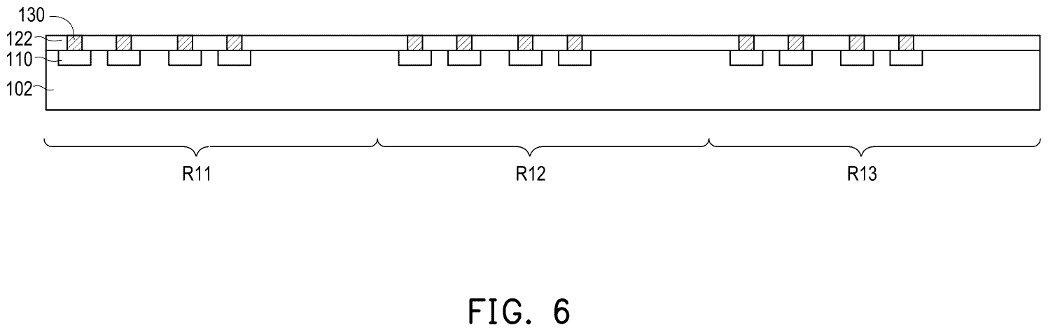

Referring to FIG. 6, after different regions of the substrate 102 are respectively exposed through the contact member photomask M2, the second photoresist layer 204 is developed (e.g., by removing the exposure region 204′ of the second photoresist layer 204) to obtain a patterned second photoresist layer (not shown). Then, the patterned second photoresist layer may be used as a mask to perform etching on the first dielectric layer 122 to form an opening (not shown). After the patterned first photoresist layer is removed, the opening is filled with a conducting material to form the contact member 130. The contact member 130 is electrically connected to the corresponding passive element 110. In FIG. 6, one contact member 130 is schematically shown to be connected to one passive element 110. However, this is not intended to limit the disclosure. A quantity of the contact member 130 may be adjusted according to the actual requirements. In addition, since the contact member photomask M1 has the blank pattern s3, each subregion of the die region 100 also has a region corresponding to the blank pattern s3. In other words, each subregion of the die region 100 has a reserved space for subsequent configuration of a through substrate via.

In some embodiments, the corresponding contact member 130 is formed on each of the plurality of passive elements 110, so that the required passive element 110 may be freely selected to be electrically connected through the corresponding contact member 130 for the subsequent distribution design.

Referring to FIGS. 7A and 7B, a through substrate via 140 is formed in the substrate 102. For example, the through base via 140 may be included in the second subregion R12 and the third subregion R13 of the die region 100. Specifically, a third photoresist layer 206 may be formed on the first dielectric layer 122 first. Then, a through substrate via photomask M3 is used as a mask, so that the through substrate via photomask M3 corresponds to a part of the second subregion R12 and the third subregion R13 to expose and develop the third photoresist layer 206 located in the part of the second subregion R12 and the third subregion R13, thereby forming the patterned third photoresist layer 206. Thereafter, the patterned third photoresist layer 206 may be used as a mask to perform etching on the first dielectric layer 122 and the substrate 102 to form an opening (not shown). Then, the opening is filled with a conducting material to form the through base via 140. In some embodiments, the patterned third photoresist layer 206 is removed before the opening is filled with the conducting material. Since each subregion of the die region 100 has the reserved space, the through substrate via 140 may be disposed in the spaces according to the actual requirements. It is noted that the through substrate via 140 may be selectively formed in a part, rather than all, of the reserved spaces. In other words, the part of the plurality of reserved spaces may not be provided with the through substrate via 140, as shown in FIG. 7A. In addition, the quantity and configuration of the through substrate via 140 formed in the reserved space of each subregion may be adjusted according to the actual requirements, and the disclosure is not limited thereto.

In some embodiments, a size of the through substrate via photomask M3 may be greater than the size of the contact member photomask M2 and the size of the passive element photomask M1, but the disclosure is not limited thereto. In other embodiments, the size of the through substrate via photomask M3 may be equal to the size of the contact member photomask M2 and the size of the passive element photomask M1. In some embodiments, the size of the through substrate via photomask M3 may be the size of a general photomask. In some embodiments, the area of the single die region 100 is about four times a single maximum exposure area of the through substrate via photomask M3.

FIG. 7A schematically shows the through substrate via 140 formed in a part of the second subregion R12 and the third subregion R13 through the through substrate via photomask M3. However, it is noted that when the single maximum exposure area of the single through substrate via photomask M3 cannot cover a pattern layout of the through substrate via 140, a plurality of through substrate via photomasks need to be spliced to complete the pattern layout of the through substrate via 140, and the through substrate via photomasks respectively have different patterns. In this embodiment, the single die region 100 requires splicing of up to four different through substrate via photomasks to complete the pattern layout of the through substrate via.

Referring to FIGS. 8A, 8B, 9A, 9B, 10, and 11, a redistribution layer 152 is formed on the substrate 102. The redistribution layer 152 is electrically connected to a part of the passive element 110 through a part of the contact member 130. Since the area of the single die region 100 is greater than the single maximum exposure area of the general photomask, a pattern layout of the redistribution layer 152 requires a plurality of exposures through a plurality of different redistribution circuit photomasks to transfer the pattern layout of the redistribution layer 152 to the die region 100.

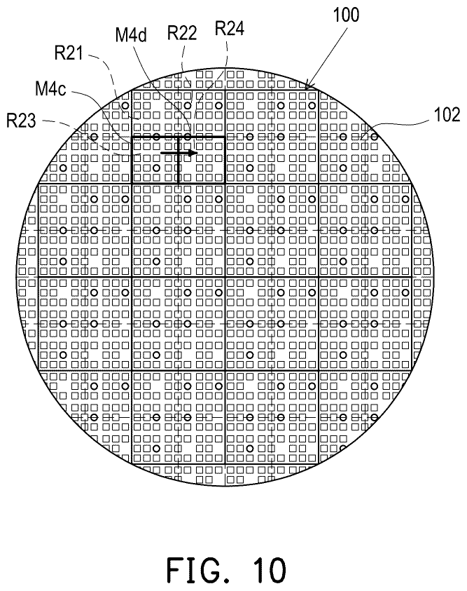

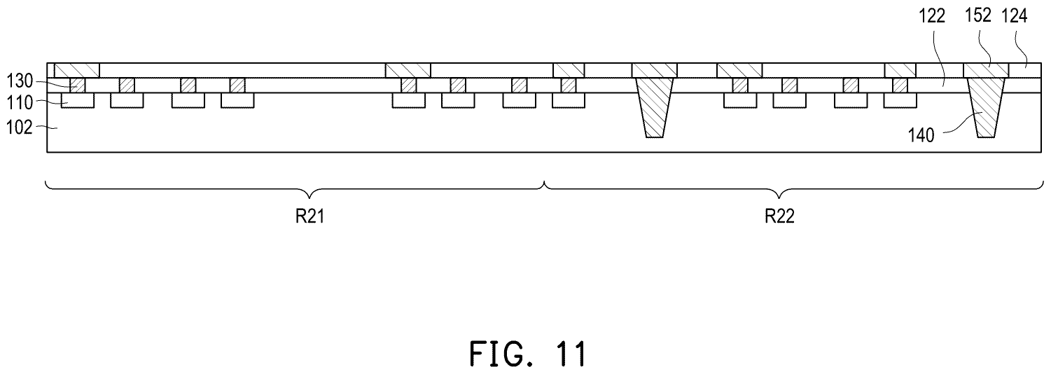

Specifically, as shown in FIGS. 8A and 8B, a second dielectric layer 124 is formed on the first dielectric layer 122. Then, a fourth photoresist layer 208 is formed on the second dielectric layer 124. Thereafter, with a first photomask M4a as a mask, the first photomask M4a is enabled to correspond to a first subregion R21 first to expose the fourth photoresist layer 208 located in the first subregion R21, and an exposure region 208′ is formed in the fourth photoresist layer 208 in the first subregion R21. Then, as shown in FIGS. 9A and 9B, a second photomask M4b is enabled to correspond to a second subregion R22 to expose the fourth photoresist layer 208 located in the second subregion R22, and the exposure region 208′ is formed in the fourth photoresist layer 208 in the second subregion R22. Similarly, as shown in FIG. 10, a third subregion R23 and a fourth subregion R24 are sequentially exposed through a third photomask M4c and a fourth photomask M4d, respectively. Thereafter, referring to FIG. 11, the fourth photoresist layer 208 is developed (e.g., by removing the exposure region 208′ of the fourth photoresist layer 208) to form a patterned fourth photoresist layer (not shown). With the patterned fourth photoresist layer as a mask, etching is performed on the second dielectric layer 124 to form an opening (not shown). After the patterned fourth photoresist layer is removed, the opening is filled with a conducting material to form the redistribution layer 152.

The first photomask M4a, the second photomask M4b, the third photomask M4c, and the fourth photomask M4d are different photomasks of the same size, each of which has a different pattern. The patterns of the first photomask M4a, the second photomask M4b, the third photomask M4c, and the fourth photomask M4d are combined to constitute the pattern layout of the redistribution layer 152. As a result, the redistribution layer 152 may be formed in a feature size that is greater than a single maximum achievable exposure range of a general photomask in length or area.

It is noted that in FIGS. 8A, 9A, and 10, to facilitate description, the single die region 100 is divided into four subregions (including the first subregion R21, the second subregion R22, the third subregion R23, and the fourth subregion R24) with dashed lines. A range of each subregion corresponds to a single maximum exposure range of the first photomask M4a (or the second subregion R22, the third subregion R23, or the fourth subregion R24). That is, in FIG. 8A, the single maximum exposure area of the first photomask M4a is one-fourth of the die region 100. In other words, the area of the single die region 100 is about four times the single maximum exposure area of the first photomask M4a. However, the single maximum exposure range of the first photomask M4a (i.e., a size of the first photomask M4a) may be adjusted according to the actual requirements, and the disclosure is not limited thereto. As the single maximum exposure range of the first photomask M4a changes, a quantity of subregions of the single die region 100 varies depending on the single maximum exposure range of the first photomask M4a.

In some embodiments, the size of the passive element photomask M1 is smaller than the size of the first photomask M4a, a size of the second photomask M4b, a size of the third photomask M4c, and a size of the fourth photomask M4d. For example, the size of the passive element photomask M1 may be 0.1 to 1 times the size of the first photomask M4a. In other embodiments, the size of the passive element photomask M1 is equal to the size of the first photomask M4a, the size of the second photomask M4b, the size of the third photomask M4c, and the size of the fourth photomask M4d.

In some embodiments, a part of the redistribution layer 152 is electrically connected to a part of the passive element 110 through a part of the contact member 130. Since the substrate 102 includes the plurality of passive elements 110 and the corresponding contact members 130, the redistribution layer 152 may be electrically connected to a part of the passive element 110 according to the distribution requirements, thereby improving the convenience of customized design. Also, the number of times of layout redesigns and quality tests of the passive element 110 and the contactor member 130 for each new product development can be reduced.

In some embodiments, the passive element 110 that is not electrically connected to the redistribution layer 152 and the corresponding contact member 130 are dummy elements.

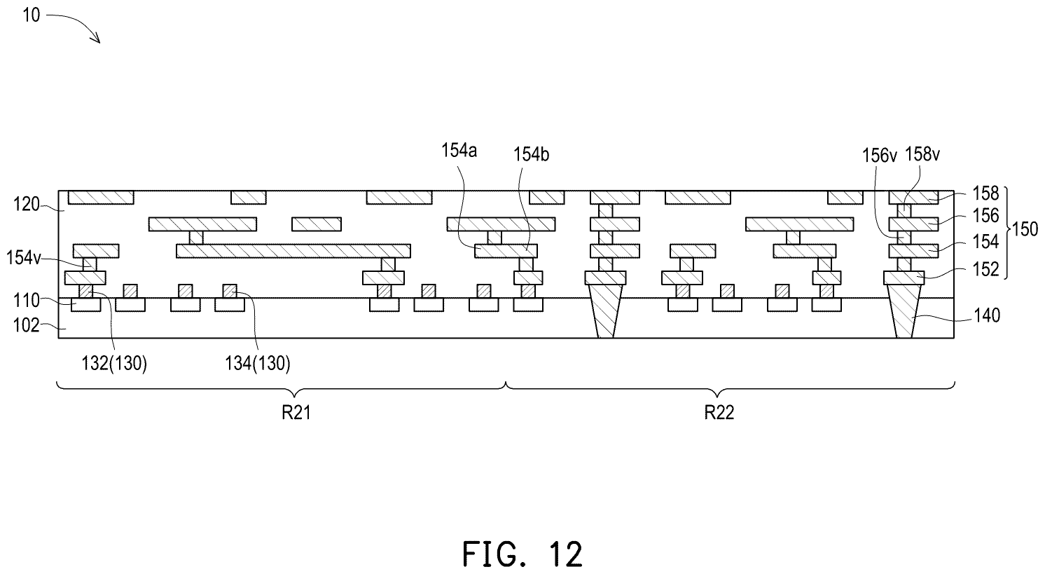

Referring to FIG. 12, a plurality of redistribution layers 154, 156, and 158 are formed on the redistribution layer 152. For example, a dielectric layer (not individually labeled) may be formed on the redistribution layer 152 first. Then, an opening (not shown) is formed in the dielectric layer through a conductive via photomask (not shown). Thereafter, a conductive material layer (not shown) is formed on the dielectric layer and in the opening, and the conductive material layer is patterned through a redistribution circuit photomask (not shown) to form the redistribution layer 154 and a conductive via 154v. Similar steps as described above are repeated to successively form the redistribution layers 156 and 158, a conductive via 156v connected between the redistribution layer 154 and the redistribution layer 156, and a conductive via 158v connected between the redistribution layer 156 and the redistribution layer 158 located in the dielectric layer 120. It is noted that the dielectric layer 120 in FIG. 12 is formed by stacking a plurality of dielectric layers (including the first dielectric layer 122 and the second dielectric layer 124). The plurality of redistribution layers 152, 154, 156, and 158 are collectively referred to as a redistribution layer 150.

Since the area of the single die region 100 is greater than the maximum achievable exposure area in a single exposure of a general photomask, the pattern layout of each of the conductive vias 154v, 156v, and 158v needs to be completed through splicing four different conductive via photomasks. The pattern layout of each of the redistribution layers 152, 154, 156, and 158 needs to be completed through splicing four different redistribution circuit photomasks.

In some embodiments, a first feature 154a of the redistribution layer 154 located in the first subregion R21 may be formed through a first redistribution circuit photomask (not shown), while a second feature 154b of the redistribution layer 154 located in the second subregion R22 may be formed through a second redistribution circuit photomask (not shown). The first feature 154a and the second feature 154b are horizontally connected. As can be seen, the redistribution layer 154 may be formed in a feature size surpassing the limitation of a single maximum exposure range of a general photomask through a photomask splicing manner.

Four redistribution layers are schematically shown in FIG. 12, but not intended to limit the disclosure. The quantity of redistribution layers and the distribution design may be adjusted according to the actual requirements.

In some embodiments, the quantity and locations of through substrate via patterns in the die region 100 may be determined first during the design stage of a layout of the die region 100. Then, a plurality of passive element patterns may be arranged in an array in the remaining substrate 102 in the die region 100, and a space may be reserved according to the pattern layout of the through substrate via. On the other hand, the distribution design of each layer of the redistribution layer 150 may be performed based on the linkage requirements. Thereafter, the redistribution layer 150 is electrically connected to the passive element 110 at a proper location according to the distribution design of the redistribution layer 150 at the bottommost layer (e.g., the redistribution layer 152). As a result, during new product development, the distribution design of the redistribution layer may be adjusted without redesigning the layout of the passive element 110 and the contact member 130, thereby easing the burden on designers and reducing development costs.

In some embodiments, a planarization process may be performed on a bottom surface of the substrate 102 to expose a bottom surface of the through substrate via 102. Then, a conductive connecting member (not shown) may be formed on the bottom surface of the through substrate via 102 to be electrically connected to the outside.

In some embodiments, a singulation process may be performed to partition the substrate 102 and a structure thereon into a plurality of semiconductor structures 10 according to the die region 100.

Through the above processes, the manufacturing method of the semiconductor structure 10 is generally completed.

The semiconductor structure 10 includes the plurality of passive elements 110, the plurality of contact members 130, and the redistribution layer 150 (including the redistribution layer 152, the redistribution layer 154, the redistribution layer 156, and the redistribution layer 158). The plurality of passive elements 110 are arranged in an array in the substrate 102. The plurality of contact members 130 are correspondingly disposed on the plurality of passive elements 110 and in direct contact with the plurality of passive elements 110. The plurality of contact members 130 include a first contact member 132 and a second contact member 134. The redistribution layer 150 is disposed on the substrate 102. The redistribution layer 150 is electrically connected to the corresponding passive element 110 through the first contact member 132, and the second contact member 134 is not electrically connected to the redistribution layer 150.

In some embodiments, the plurality of conductive vias 154v, 156v, and 158v are connected between the adjacent redistribution layers 150 to provide the redistribution layer 150 with an electrical connection in a vertical direction.

In some embodiments, the passive element 110 in direct contact with the second contact member 134 is a dummy passive element.

In some embodiments, the semiconductor structure 10 further includes the dielectric layer 120. The dielectric layer 120 is disposed on the substrate 102 and laterally surrounds the plurality of contact members 130 and the redistribution layer 150. A top surface of the second contact member 134 is encapsulated by the dielectric layer 120. That is, the second contact member 134 is a dummy contact member.

In some embodiments, the semiconductor structure 10 further includes the through substrate via 140 disposed in the substrate 102 to provide electrical connections on both sides of the substrate 102.

In some embodiments, the through substrate via 140 is also embedded in a part of the dielectric layer 120. The top surface of the contact member 130 may be flush with the top surface of the through substrate via 140.

In some embodiments, the semiconductor structure 10 may serve as an interposer to be connected between a chip and a circuit board.

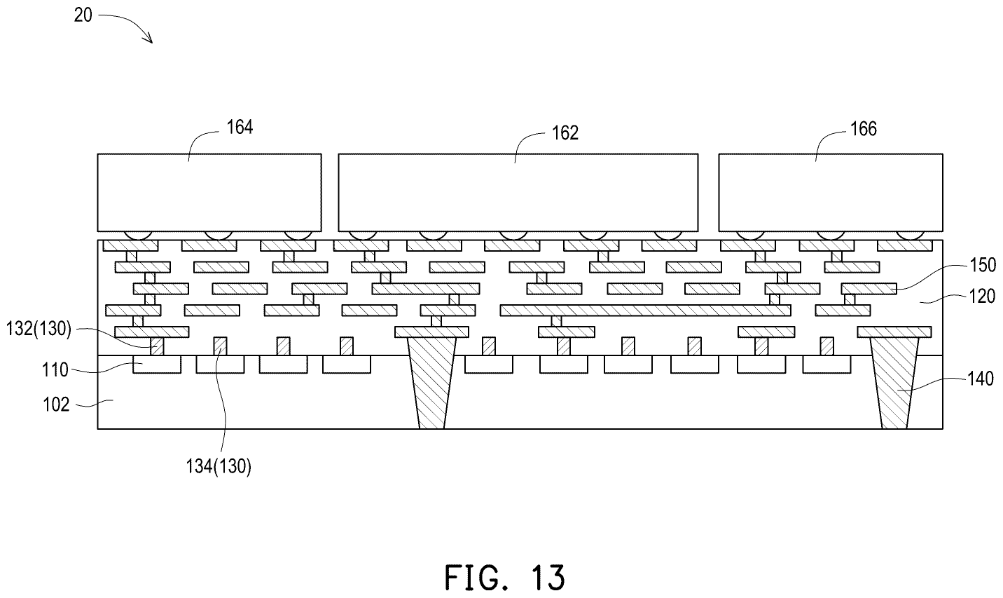

FIG. 13 is a cross-sectional schematic diagram of a semiconductor structure according to an embodiment of the disclosure. It should be noted herein that, the embodiment of FIG. 13 continues to use the reference numerals and some content of the embodiment of FIG. 12, wherein the same or similar reference numerals are adopted to represent the same or similar elements, and description of the same technical content is omitted. For the description of the omitted part, reference may be made to the foregoing embodiment, which will not be repeated.

Referring to FIG. 13, a semiconductor structure 20 includes the plurality of passive elements 110, the plurality of contact members 130, and the redistribution layer 150. The plurality of passive elements 110 are arranged in an array in the substrate 102. The plurality of contact members 130 are correspondingly disposed on the plurality of passive elements 110 and in direct contact with the plurality of passive elements 110. The plurality of contact members 130 include a first contact member 132 and a second contact member 134. The redistribution layer 150 is disposed on the substrate 102. The redistribution layer 150 is electrically connected to the corresponding passive element 110 through the first contact member 132, and the second contact member 134 is not electrically connected to the redistribution layer 150.

The semiconductor structure 20 is generally similar to the semiconductor structure 10. The semiconductor structure 20 differs from the semiconductor structure 10 in that the semiconductor structure 20 further includes a plurality of chips 162, 164, and 166 disposed on the dielectric layer 120. The plurality of chips 162, 164, and 166 may be electrically connected to the redistribution layer 150 though a conductive connecting member (not labeled).

In some embodiments, the chip 162 is located between the chip 164 and the chip 166. In some embodiments, the chip 162 may be a system on chip, and the chips 164 and 166 may be high bandwidth memories. However, the disclosure is not limited thereto.

In summary, in the disclosure, the plurality of passive elements arranged in the array are formed in the substrate using the same photomask, and the required passive element is selected for an electrical connection using the distribution design of the redistribution layer. As a result, the burden of the layout design of the plurality of passive elements in the substrate can be reduced, and the flexibility of customization can be improved. In terms of manufacturing, the requirement for manufacturing the photomask of the plurality of passive elements can also be reduced, thereby reducing the manufacturing costs.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A manufacturing method of a semiconductor structure, comprising:
forming a plurality of passive elements in a substrate, wherein the plurality of passive elements are arranged in an array in the substrate;
forming a plurality of contact members on the plurality of passive elements, the plurality of contact members corresponding to the plurality of passive elements; and
forming a redistribution layer on the substrate, wherein the redistribution layer is electrically connected to a part of the plurality of passive elements through a part of the plurality of contact members.

2. The manufacturing method of the semiconductor structure of claim 1, wherein forming the plurality of passive elements in the substrate comprises:
respectively exposing different regions of the substrate through a passive element photomask.

3. The manufacturing method of the semiconductor structure of claim 1, wherein forming the plurality of contact members on the plurality of passive elements comprises:
respectively exposing different regions of the substrate through a contact member photomask.

4. The manufacturing method of the semiconductor structure of claim 2, wherein forming the redistribution layer on the substrate comprises:
enabling a first photomask to correspond to a first subregion, and forming a first feature of the redistribution layer in the first subregion of the substrate through the first photomask; and
enabling a second photomask to correspond to a second subregion, and forming a second feature of the redistribution layer in the second subregion of the substrate through the second photomask, wherein a pattern of the first photomask is different from a pattern of the second photomask.

5. The manufacturing method of the semiconductor structure of claim 4, wherein the first feature and the second feature are horizontally connected.

6. The manufacturing method of the semiconductor structure of claim 4, wherein the substrate comprises a plurality of die regions, and an area of each of the plurality of die regions is greater than a single maximum exposure area of the first photomask.

7. The manufacturing method of the semiconductor structure of claim 6, wherein a size of the passive element is smaller than a size of the first photomask.

8. The manufacturing method of the semiconductor structure of claim 1, wherein a part of the plurality of passive elements is a dummy passive element.

9. The manufacturing method of the semiconductor structure of claim 1, further comprising: forming a through substrate via in the substrate.

10. A semiconductor structure, comprising:
a plurality of passive elements, arranged in an array in a substrate;
a plurality of contact members, correspondingly disposed on the plurality of passive elements and in direct contact with the plurality of passive elements, wherein the plurality of contact members comprise a first contact member and a second contact member; and
a redistribution layer, disposed on the substrate, wherein the redistribution layer is electrically connected to the corresponding passive element through the first contact member, and the second contact member is not electrically connected to the redistribution layer.

11. The semiconductor structure of claim 10, further comprising:
a dielectric layer, disposed on the substrate and laterally surrounding the plurality of contact members and the redistribution layer, wherein a top surface of the second contact member is encapsulated by the dielectric layer.

12. The semiconductor structure of claim 10, further comprising:
a through substrate via, disposed in the substrate, wherein a top surface of the plurality of contact members is flush with a top surface of the through substrate via.
